(19) United States
(12) Patent Application Publication
(10) Pub. No.: US 2003/0151425 A1
(43) Pub. Date: Aug. 14, 2003

(54) ASYNCHRONOUS SERIAL POLL CIRCUIT

(76) Inventor: Michael S. Hagedorn, Orlando, FL (US)

Correspondence Address: STEPTOE & JOHNSON LLP, c/o Stuart T.F. Huang, 1330 Connecticut Avenue, NW, Washington, DC, 20036, US

(21) Appl. No.: 10/073,044

(22) Filed: Feb. 12, 2002

(51) Int. Cl. H03K 19/23

(52) U.S. Cl. 326/35

(57) ABSTRACT

A serial poll request node and circuit are provided. The node includes a data token input and output, first and second acknowledge inputs, and an arbitrating switch. An acknowledge circuit is configured to receive as an input the first and second acknowledge inputs and at least one output of the arbitrating switch, and to generate an enable signal in response to at least the absence of a pending request signal and both the first and second acknowledge inputs simultaneously receiving acknowledge signals.

### BACKGROUND OF THE INVENTION

1. Field of the Invention

The invention relates to an asynchronous serial poll circuit. In particular, the invention relates to a serial poll network that includes a control node and at least two request nodes operating in an asynchronous fashion.

2. Discussion of Background Information

Asynchronous circuits do not require a clock for synchronizing signals. One asynchronous logic paradigm (Null Convention Logic™) is disclosed in U.S. Pat. No. 5,305,463, which is incorporated by reference herein in its entirety. Several data representations are discussed, but in one representation, a signal may assume a DATA value or a NULL value. A DATA value for example, might be a numeric zero or one, or a logic TRUE or FALSE, or another meaning not related to binary or Boolean logic representations. For example, in a line capable of carrying electrical signals, when the line is active, that is, when the line is actively carrying current, this condition may represent a DATA, or asserted, value. Similarly, when such a line carries no current, it may be said to represent a NULL value. Alternately, negative logic is possible; for example a line with no current may be said to indicate a TRUE or DATA value. Examples of U.S. patents that disclose related technology are U.S. Pat. Nos. 5,305,463; 5,656,948; 5,664,211; and 6,043,674.

A serial poll in a network environment includes a bus connected to a control node and to at least two request nodes. The bus provides the connections among the various nodes on the network. Each node passes a poll token along a data path from an adjacent upstream node to an adjacent downstream node. The control node is associated with a controller, typically a computer, which serves a plurality of peripheral devices. Each peripheral device is associated with a request node on the bus, and may request service by causing its corresponding request node to activate its request terminal. The controller activates the control node to poll each device through the device's associated request node to determine if the device requires service.

The controller polls each device in a serial manner to determine if service is required. This ensures that the bus carries only one signal at a time. For the control node to initiate a poll of the request nodes on the bus, the control node sends the poll token through the bus. This token is an electrical signal, which is exchanged by the request nodes in turn. When the token reaches a node that is requesting service, it causes the request node to send a go-ahead signal to the associated device. In this way, each device on the bus may receive service from the controller associated with the control node, without collisions occurring on the bus. The term “token” is used synonymously with “poll token” herein.

A hazard is an unintended change in a signal or signal anomaly. Usually such changes are brief, unexpected, or unpredictable “glitches” in a signal. For example, a signal may change from a first state to a second state and back to the first state when it should remain constant in the first state.

A circuit is metastable if its operations are fragile and easily upset, or if it has only minimal stability. Circuits that are metastable are susceptible to perturbations. For example, instead of a clean transition between states, the signal may alternate several times from one state to another before settling on the final state. Any small change in a signal may cause a metastable circuit to behave abnormally or “crash”. As such, metastabilities are generally regarded as undesirable in circuit design, and are avoided if possible.

A circuit is delay-insensitive if it operates correctly regardless of delays in components or connections. Some circuits are susceptible to problems due to skew between signals at different parts of the circuit. When delay occurs between a clock and data signal, for example, a hazard called a race may result. Delays cause signals to be out of synch and therefore may cause data loss or other problems associated with hazards. In general, circuits that are delay-insensitive are also hazard free and free from metastabilities.

Race conditions are problems for circuits that employ clocks. A race condition occurs when the clock signal lags behind the data signal at parts of a circuit, e.g., when the clock signal is skewed behind the data signals. This condition can cause a data cycle to be lost because it cannot be correctly latched by the clock signal. A circuit that avoids race conditions is called race-free.

A mutex gate (“mutex”), as described by C. L. Seitz, can act as an arbiter, but with stable outputs. A simple mutex has two inputs, REQUEST A and REQUEST B, and two outputs, GRANT A and GRANT B. A mutex of this type operates according to the following parameters:

(1) If REQUEST A (RA) and REQUEST B (RB) are both inactive, then GRANT A (GA) and GRANT B (GB) will also be inactive.

(2) If REQUEST A is active while REQUEST B is inactive, then GRANT A will be active and GRANT B will be inactive; REQUEST A is thus granted.

(3) If REQUEST A is inactive while REQUEST B is active, then GRANT A will be inactive and GRANT B will be active; REQUEST B is thus granted.

(4) If REQUEST A and REQUEST B are active simultaneously, then only one of GRANT A and GRANT B will be active, while the other is inactive. The selection of the active output is random, but can be influenced by external conditions (e.g., temperature) or construction irregularities. When both requests are active simultaneously and a first request is granted, then not until the granted input is de-asserted will the mutex allow the other input to flow through to its corresponding output. In short, a mutex arbitrates to grant one request at a time, even if both are coincidentally active.

### SUMMARY OF THE INVENTION

The present invention provides an asynchronous serial poll circuit that is preferably race-free, free from metastabilities, free from hazards, and delay insensitive.

According to a preferred embodiment of the invention, a serial poll request node is provided. The node includes a data token input and output, first and second acknowledge inputs, and an arbitrating switch. An acknowledge circuit is configured to receive as an input the first and second acknowledge inputs and at least one output of the arbitrating switch, and to generate an enable signal in response to at least the absence of a pending request signal and both the first and second acknowledge inputs simultaneously receiving acknowledge signals.

Various optional and preferable features of the above embodiment include that the arbitrating switch is a mutex, and a peripheral device configured to send a request signal to the serial poll request node.

According to another embodiment of the invention, a serial poll circuit is provided. A plurality of nodes each includes a data token input and output, first and second acknowledge inputs, an arbitrating switch, and an acknowledge circuit capable of generating an enable signal in response to at least the absence of a pending request signal and both the first and second acknowledge inputs simultaneously receiving acknowledge signals. The first and second acknowledge inputs are capable of receiving acknowledge signals from different sources.

Various optional and preferable features of the above embodiment include the second acknowledge input is configured to receive an acknowledge signal from a downstream one of the plurality of nodes in the data path, and the downstream one of the plurality of nodes is two nodes downstream. The embodiment may include a plurality of peripheral devices, at least some of the nodes are request nodes, and each of the request nodes are connected to one of the plurality of peripheral devices. The embodiment may include the plurality of nodes being request nodes, and a control node at least partially controlling the plurality of nodes.

According to another embodiment of the invention, a serial poll request node includes an arbitrating switch, a poll token input and output, a request input, and a logic gate. The request token input and the request input are fed into the arbitrating switch. An output of the arbitrating switch and the data token input are fed into the logic gate. A go output is connected to an output of the logic gate. A token received at the poll token input will not pass to the poll token output when a request signal is pending at the request input.

A preferable feature of the above embodiment is a peripheral device configured to send a request signal to the serial poll request node.

According to yet another embodiment of the present invention, a serial poll circuit includes a plurality of nodes along a data path. Each node includes a data token input and output, first and second acknowledge inputs, an arbitrating switch, and an acknowledge circuit capable of generating an enable signal in response to at least both the first and second acknowledge inputs simultaneously receiving acknowledge signals. A token received at the data token input will pass to the data token output in the presence of the enable signal. The first and second acknowledge inputs are capable of receiving acknowledge signals from different sources.

According to various preferable features of the above embodiment, the different sources include one of the plurality of nodes that is two nodes downstream. A preferable combination of features includes a plurality of peripheral devices, at least some of the plurality of nodes being request nodes, and each of the request nodes being connected to one of the plurality of peripheral devices. In another combination, the plurality of nodes are request nodes, and a control node at least partially control the plurality of nodes.

According to still yet another embodiment of the invention, a serial poll circuit includes a plurality of nodes along a data path. At least some of the nodes include a poll token input and output, first and second acknowledge inputs, an arbitrating switch, and an acknowledge circuit capable of generating an enable signal in response to at least both the first and second acknowledge inputs simultaneously receiving acknowledge signals. A token received at the poll token input will pass to the poll token output in the presence of the enable signal. The first and second acknowledge inputs are capable of receiving acknowledge signals from two other different ones of the plurality of nodes.

Various preferable and optional features of the above embodiment include that the second acknowledge input is capable of receiving an acknowledge signals from a downstream one of the plurality of nodes in the data path, and the downstream one of the plurality of nodes is two nodes downstream. A preferable combination includes a plurality of peripheral devices, at least some of the plurality of nodes being request nodes, and each of the request nodes being connected to one of the plurality of peripheral devices. In another combination, the plurality of nodes are request nodes, and a control node at least partially controls the plurality of nodes.

According to another embodiment of the invention, a serial poll circuit includes a plurality of request nodes along a data path. Each node includes a data token input and output, first and second acknowledge inputs, an arbitrating switch, and an acknowledge circuit capable of generating an enable signal in response to at least both the first and second acknowledge inputs simultaneously receiving acknowledge signals. A token received at the data token input will pass to the data token output in the presence of the enable signal. At least one of the request nodes further includes the first acknowledge input being capable of receiving an acknowledge signal from an adjacent upstream one of the plurality of nodes in the data path, and the second acknowledge input being capable of receiving an acknowledge signal from a downstream one of the plurality of nodes in the data path.

Various optional and preferable features of the above embodiment include the second acknowledge input being capable of receiving an acknowledge signal from one of the plurality of nodes in the data path that is two nodes downstream and a peripheral device operating in connection with the serial poll request node.

According to a yet another embodiment of the invention, a serial poll request node includes a request input terminal, a go output terminal, an acknowledge two-prior input terminal, a mutex, a first input and corresponding first output of the mutex, a second input and corresponding second output of the mutex, a hysteresis gate, and a threshold gate. The first input to the mutex is connected to a first input to the threshold gate. The second input to the mutex is connected to the request input terminal. The first output of the mutex is connected to a first input to the hysteresis gate. The second output of the mutex is connected to a second input to the threshold gate. The acknowledge two-prior input terminal is connected to a second input of the hysteresis gate.

According to still yet another embodiment of the invention, a serial poll circuit is provided. A plurality of nodes include a plurality of request nodes and a control node at least partially controlling the plurality of request nodes. A first data path, defined by the plurality of nodes, is configured to transmit a token along the first data path. A second data path, different from the first data path, includes the plurality of nodes, and is configured to transmit a first acknowledge signal along the second data path from one of the plurality of nodes to the next adjacent upstream node. A third data path, including the plurality of request nodes, is configured to transmit a second acknowledge signal along the third data path from one of the plurality of request nodes to the second adjacent downstream one of the request nodes. Each of the request nodes transmits the token in accordance with the first and second acknowledge signals received along the second and third acknowledge signals.

Other exemplary embodiments and advantages of the present invention may be ascertained by reviewing the present disclosure and the accompanying drawings.

### BRIEF DESCRIPTION OF THE DRAWINGS

The present invention is further described in the detailed description which follows, in reference to the noted plurality of drawings by way of non-limiting examples of certain embodiments of the present invention, in which like numerals represent like elements throughout the several views of the drawings, and wherein:

FIG. 1 is a circuit schematic of an asynchronous serial poll request node.

FIG. 2 is a circuit schematic of an asynchronous serial poll control node.

FIG. 3 is a circuit schematic of an asynchronous serial poll network.

FIG. 4 is a block diagram of a peripheral device that operates in conjunction with a serial poll request node of FIG. 1.

### DETAILED DESCRIPTION OF THE EXEMPLARY EMBODIMENT

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

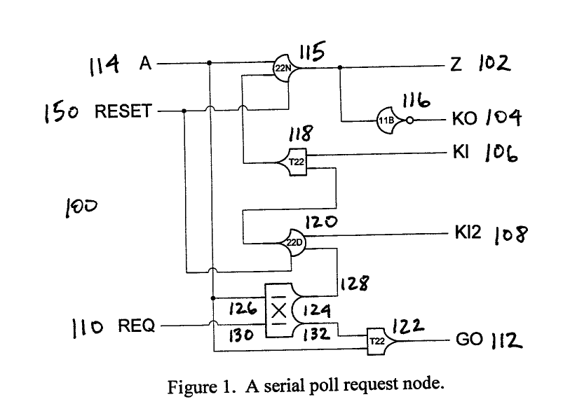

FIG. 1 illustrates an embodiment of an asynchronous serial poll request node 100. Node 100 is configured to receive a data input token at input terminal 114 (A) and a request signal at input terminal 110 (REQ). Node 100 is also configured to receive a first acknowledge signal at 106 (KI) and a second acknowledge signal at 108. Node 100 can output a token at terminal 102 (Z) or a GO signal at terminal 122 (GO) in response to a request signal under circumstances as described below. A reset terminal 150 is configured to receive a reset command that will initialize the circuit, which occurs after power-up.

The internal components of node 100 are as follows. A mutex 124 has a first input connected to request terminal 110 and a second input connected to poll token input terminal 114. A first output 132 of mutex 124 and poll token input 114 are inputs to a first gate 122, which is a two of two threshold gate without hysteresis that functions as an AND gate. The second output 128 of mutex 124 and the second acknowledge terminal 108 connect as inputs to a second gate 120, which is a resettable two of two threshold gate with hysteresis that resets to DATA. The output of second gate 120 and first acknowledge input 106 supply inputs to a third gate 118. Third gate 118 is a two of two threshold gate without hysteresis that functions as an AND gate. The output of third gate 118 and token input terminal 114 are inputs for fourth gate 115. Fourth gate 115 is a resettable two of two threshold gate with hysteresis that resets to NULL. The output of fourth gate 115 input into fifth gate 116 and also into token output terminal 102 (Z). Fifth gate 116 is a logical inverter, or “bar” gate. The output of fifth gate 116 connects to acknowledge output terminal 106 (KO). Reset terminal 150 connects to the reset controls of second gate 120 and fourth gate 115.

The aforementioned gates and their operations are described in, for example, U.S. Pat. Nos. 5,640,105, 5,656,948, 5,664,211, 5,977,663, 6,020,754, and 6,043,674.

Due to the nature of mutex 124, the operation of node 100 is dependent upon both the state of the input signals and the order in which they are received. Thus, if a request signal is received before a poll token, mutex 124 will pass the request signal to first gate 122. First gate 122, which acts as an AND gate, will issue a GO command at terminal 112 when node 100 receives a subsequent token at terminal 114. Thus, node 100 will issue a GO command when a pending request signal is followed by a token. Under normal operation, node 100 cannot pass a received token to output terminal 102 (Z) while request terminal 110 is active, i.e., when a request is pending.

Similarly, if node 100 receives the token before the request signal, mutex 124 will pass the token through the second output 128 of mutex 124 into the acknowledge circuitry of node 100 to determine if it is appropriate to pass the token to the Z output. The acknowledge circuitry of node 100 includes second and third gates, 120, 118, their connections, and first 106 and second 108 acknowledge input terminals. During this time, the exclusive nature of the output of mutex 124 will prevent a subsequently received request signal from passing to first gate 122, or otherwise issuing a GO output.

Request node 100 requires that the acknowledge circuitry provides an enable signal before the token can pass to output terminal 102. As noted above, this signal depends at least partially on the current state of the inputs and the order received.

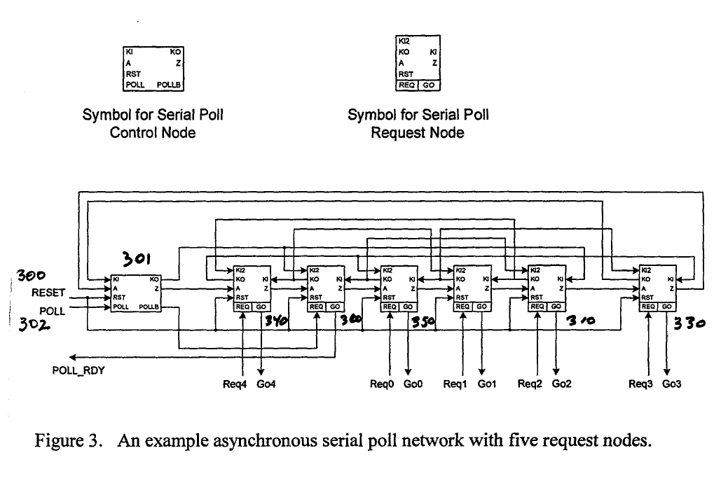

FIG. 3 illustrates one embodiment of the asynchronous serial poll network circuit. The nodes are arranged in a ring structure, similar to a ring of registers. The ring includes a control node 301 and five identical request nodes 310, 320, 330, 340, and 350 (i.e., each having the structure shown in FIG. 1). The illustrated embodiment can be used to implement a serial poll function that polls each bit in order one time only. Alternately, this embodiment can be used for continuous cycling of this function until POLL is released.

For request nodes, each receives acknowledgement at KI from the adjacent downstream node's KO and receives acknowledgement at KI2 from the second adjacent upstream node's KO. Likewise, each node's KO signals both the adjacent upstream node's KI and the second adjacent downstream node's KI2.

The A-Z input/output connections link through each node in the token data path. The A terminal 114 and Z terminal 102 are configured to pass a poll token from one node to the next adjacent downstream node in the token data path. The A terminal 114 receives the poll token from the adjacent upstream node on the network, and the Z terminal 102 outputs the poll token to the adjacent downstream node on the network. In this manner, the token passes through all of the network nodes until it reaches a node that has requested service. When the request node with a pending request receives the poll token at input terminal 114, it activates GO terminal 112. The Z terminal 102 remains active until the request terminal 110 is inactive. When the request terminal 110 is de-asserted, the token is allowed to pass through the node and on to the next downstream node. Acknowledgement elements hold the token at the requesting node until the request is complete.

Acknowledgement functions are performed by the acknowledge output terminal 104, the acknowledge input terminal 106, the acknowledge two-prior terminal 108, second gate 120 and third gate 118. Because the circuit is asynchronous, no clock is required to synchronize the signals amongst the nodes. Instead, the nodes coordinate their functions by way of feedback among the acknowledgement terminals.

The acknowledge output terminal 104 reports the opposite signal from the Z token output terminal 102 by nature of inverted gate 116. Hence, if the token is active at the Z output of a given node, the acknowledge output terminal 104 is inactive. Conversely, if the token is not present at the Z terminal 102 of a given node, that node has an active acknowledge output terminal 104. The acknowledge output terminal 104 of a given node provides information to the both the prior node and the second successor node.

The KO-KI data path provides feedback as the token travels in the token data path. Terminal KI 106 is the acknowledge input, which receives a signal passed from the KO 104 terminal of the next downstream node along this data path in the serial poll. This signal provides an indication of whether an adjacent downstream node is transferring the token. This mechanism allows the present node to preserve token integrity.

The KO-KI2 data path maintains the token in at most the A-Z terminals of a single node. The KI2 terminal 108 is the acknowledge two-prior terminal, which receives a signal at a given node from the KO terminal 104 from the second node upstream in this acknowledgement data path. In this data path, the signal may pass directly to the second adjacent downstream node, or it may additionally travel through the control node. The KI2 input 108 is used to halt the token (on A) at the given node when a request needs to be serviced. This mechanism also prevents the token from spanning three nodes at once. As part of normal operation, a token may span two nodes at the same time.

An n-bit request structure requires n+1 request nodes, including n request nodes and one special acknowledge/ready node. The acknowledge/ready node is the node downstream from the node being driven by the control node's Z output. The POLLB output 210 of the control node is connected to the request node of the acknowledge/ready node. The associated go terminal of the acknowledge/ready node becomes an indicator that the network is ready to poll 304 (POLL_RDY). Accordingly, the poll ready indicator is de-asserted when the circuit is actively polling.

The control node is inserted into the ring of request nodes to create a start/stop point and to initialize a token in the ring. The ring is broken between two nodes and the KO and Z outputs of the break are connected to the KI and A on the control node, respectively. The KO and Z outputs of the control node replace those of the request node at the break. When the control node reset terminal is asserted, the control node modifies the data between two nodes along the KO/KI and Z/A terminals to insert a data token into the network.

Upon power up, and with no terminals activated on the control node, the circuit behaves as follows. Because the control node's poll terminal is not asserted, POLLB is asserted and activates the request terminal downstream at the acknowledge/ready node. This causes the mutex in that node to choose the corresponding output 132 leading to threshold gate 122. None of the A or Z terminals in any of the nodes are active at this point, so that all of the KO outputs of the nodes and each of the K1 and K12 input terminals on each of the nodes are asserted. In simple terms, there is no token yet in the circuit, and each node is fully acknowledged and ready.

The next step in operating the circuit is to insert a token into the network. This is accomplished by activating the reset terminal 300 at the control node. The poll terminal 302 is still not yet activated. Resetting the circuit engages the threshold gate 214, which de-asserts the output of gate 216, causing the Z terminal 202 of the control node to become active. Accordingly, the control node's KO 204 de-asserts, which reaches the acknowledge/ready node's KI2 and the second upstream request node's KI. The token then travels downstream through node 340, to the A terminal of the acknowledge/ready node. Because POLLB is active, the mutex in the acknowledge/ready node prevents the token from reaching the node's Z output. Thus, the token is now present at both A and Z terminals of the fourth request node (340). The control node has also de-asserted the acknowledge/ready node's KI2. The reset terminal of the control node is deasserted, and the circuit's mode is unchanged.

Now the circuit is ready to poll. To illustrate a typical operation, presume that the device corresponding to request node 310 has asserted its request terminal Req1, and that no other request nodes have requested service. Again, this presumption is non-limiting; any node or plurality of nodes may request service at any time. After verifying that the reset terminal of the control node is de-asserted, polling may commence by asserting the poll terminal 302 on the control node. This causes several events. First, in the control node, token output terminal 202 is de-asserted, and 204 KO is asserted. Note that the hysteresis gate 214 does not deactivate until both of its inputs are de-asserted. Next, POLLB is de-asserted. This action releases the mutex in the acknowledge/ready node. In turn, POLL_RDY 304 de-asserts, and the token flows to the acknowledge/ready node's Z terminal. The acknowledge/ready node's KO alerts request node 340 at its KI terminal, which cuts the token off at the Z terminal of request node 340. The acknowledge two-prior terminal of request node 310 is likewise de-asserted.

The token then flows downstream until it reaches the A terminal of request node 310. Again, this presumes by way of a non-limiting example that the request terminal of request node 350 is not asserted and the request terminal of request node 310 is asserted. At request node 310, the active request terminal signal passes through mutex 124 at output 132 to first gate 122. When the token reaches first gate 122, GO terminal 112 activates, and mutex 124 belays the input signal appearing at 126. At this point, neither input to second gate 120 of request node 310 is active, so the output of this gate is de-asserted. This action blocks the output of third gate 118, which stops the token from flowing to the Z terminal of request node 310.

After the device associated with request node 310 is complete with the request, it de-asserts the request line Req1. This releases mutex 124 at this node, terminates the GO signal at 112, and allows the token to flow downstream to the next request node 320. In this manner, the token passes to each request node in turn, pausing at nodes with active request lines, until theses lines are de-asserted. The token will cycle once through the network, and continue on for additional cycles until poll 301 of the control node is de-asserted.

The invention is not limited to the 5-bit serial poll structure of FIG. 3; asynchronous serial poll networks having any number of request nodes may be built consistent with the disclosure herein. The circuit is modular and easily expandable.

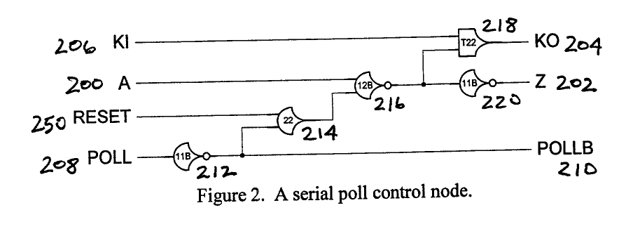

FIG. 2 illustrates an embodiment of the asynchronous serial poll control node. The poll terminal 208 (POLL) causes the control node to begin polling the request nodes on the network. The POLLB output is linked to the request node of a special acknowledge/ready node on the network, explained further below. For normal operation of the control node, the poll terminal must be de-asserted when Reset is asserted.

The internal configuration of the control node illustrated in FIG. 2 is described presently. A poll terminal 208 is connected to the input of first gate 212, which is a logical inverter. The output of first gate 212 and reset terminal 250 are input to a second gate 214, which is a two of two threshold gate with hysteresis that functions as a logical AND gate with hysteresis. The output of first gate 212 is also connected to POLLB terminal 210. The output of second gate 214 and token input terminal 200 (A) are inputs for a third gate 216, which is a one of two threshold gate with inversion and hysteresis, i.e., this gate is a logical NOR gate with hysteresis. The output of third gate 216 and acknowledge input terminal 206 provide inputs for fourth gate 218 which is a two of two threshold gate, a logical AND gate. The output of fourth gate 218 connects to acknowledge output terminal 204 (KO). Fifth gate 220 receives an input from the output of third gate 216, and outputs to a token output terminal 202. Fifth gate 220 is also a logical inverter.

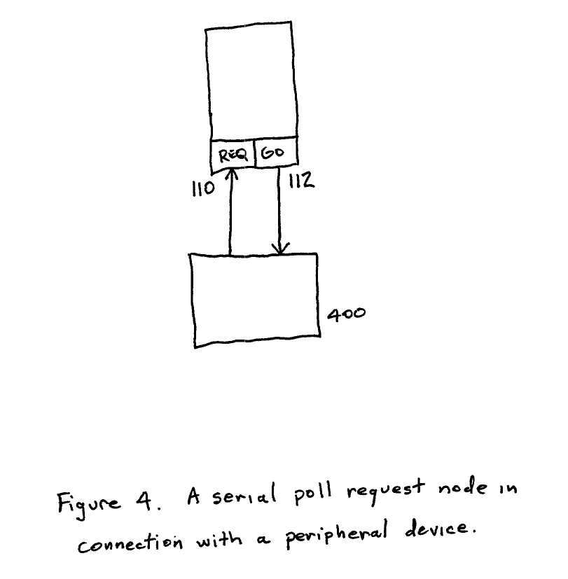

The request terminal is activated by the request node's associated device 400 (FIG. 4) when device 400 is ready to receive service from the controller. As the controller polls the devices, the requesting node is recognized by way of this request terminal 110. Likewise, the GO terminal 112 of the request node tells the requesting device to go ahead. The requesting node activates the GO terminal when a poll token reaches it, the mechanism of which is further described below. That is, at the appropriate time, the go terminal indicates to the associated requesting device that it may proceed.

The circuit can be used to implement stacked interrupts by adding a reset acknowledge and resetting the circuit after servicing the highest priority outstanding request. In the illustrated embodiment, the serial poll circuit is “fair” in that it will poll and service each outstanding request in order before it can repeat the process. With slight modifications, the circuit can be used to service the highest priority outstanding request in an “unfair” process. By adding a reset acknowledge and resetting the circuit after acknowledging the highest priority request, the serial poll can be restarted to find the next request. This method can be used to stack interrupts.

The circuit can be used to implement race free request polling or arbitration. The circuit can be used as a fair resource arbiter by ORing the request lines together and driving the POLL input with the result. With this setup, if there are no outstanding requests the circuit is idle. If there are outstanding requests, the circuit will poll around the ring however many times are required to service each request in order until there are no more requests.

The illustrated embodiment uses Null Convention Logic™, however, other systems of asynchronous logic may be used. In addition, other circuit configurations or elements that perform the noted functions may be used in place of the elements described in the embodiments herein. It is noted that the present invention may be used in positive or negative logic. To the extent that the embodiments herein use positive logic, the modification for negative logic is within the abilities of one skilled in the art. The various “signals” disclosed herein may be HIGH, LOW, ASSERTED, NULL, etc.

It is noted that the foregoing examples have been provided merely for the purpose of explanation and are in no way to be construed as limiting of the present invention. While the present invention has been described with reference to certain embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

What is claimed is:

1. A serial poll request node, comprising:
a data token input and output;
first and second acknowledge inputs;
an arbitrating switch;
an acknowledge circuit configured to receive as an input said first and second acknowledge inputs and at least one output of said arbitrating switch, and to generate an enable signal in response to at least the absence of a pending request signal and both said first and second acknowledge inputs simultaneously receiving acknowledge signals.

2. The serial poll request node of claim 1, wherein said arbitrating switch is a mutex.

3. The serial poll request node of claim 1, further comprising a peripheral device configured to send a request signal to said serial poll request node.

4. A serial poll circuit comprising:
a plurality of nodes, each comprising:
a data token input and output;
first and second acknowledge inputs;
an arbitrating switch; and
an acknowledge circuit capable of generating an enable signal in response to at least the absence of a pending request signal and both said first and second acknowledge inputs simultaneously receiving acknowledge signals;
wherein said first and second acknowledge inputs are capable of receiving acknowledge signals from different sources.

5. The serial poll circuit of claim 4 wherein said second acknowledge input is configured to receive an acknowledge signals from a downstream one of said plurality of nodes in said data path.

6. The serial poll circuit of claim 5 wherein said downstream one of said plurality of nodes is two nodes downstream.

7. The serial poll circuit of claim 4 further comprising:
a plurality of peripheral devices;
at least some of said nodes being request nodes; and
each of said request nodes being connected to one of said plurality of peripheral devices.

8. The serial poll circuit of claim 4, further comprising said plurality of nodes being request nodes; and a control node at least partially controlling said plurality of nodes.

9. A serial poll request node, comprising:
an arbitrating switch;
a poll token input and output;
a request input; and
a logic gate;
said request token input and said request input being fed into said arbitrating switch;
an output of said arbitrating switch and said data token input being fed into said logic gate; and
a go output connected to an output of said logic gate;
wherein a token received at said poll token input will not pass to said poll token output when a request signal is pending at said request input.

10. The serial poll request node of claim 9 further comprising a peripheral device configured to send a request signal to said serial poll request node.

11. A serial poll circuit comprising:
a plurality of nodes along a data path, each comprising:
a data token input and output;
first and second acknowledge inputs;
an arbitrating switch; and
an acknowledge circuit capable of generating an enable signal in response to at least both said first and second acknowledge inputs simultaneously receiving acknowledge signals;
wherein a token received at said data token input will pass to said data token output in the presence of said enable signal; and
wherein said first and second acknowledge inputs are capable of receiving acknowledge signals from different sources.

12. The serial poll circuit of claim 11 wherein said different sources include one of said plurality of nodes that is two nodes downstream.

13. The serial poll circuit of claim 11 further comprising:
a plurality of peripheral devices;
at least some of said plurality of nodes being request nodes; and
each of said request nodes being connected to one of said plurality of peripheral devices.

14. The serial poll circuit of claim 11, further comprising said plurality of nodes being request nodes; and a control node at least partially controlling said plurality of nodes.

15. A serial poll circuit comprising:
a plurality of nodes along a data path, at least some of said nodes comprising:
a poll token input and output;
first and second acknowledge inputs;
an arbitrating switch; and
an acknowledge circuit capable of generating an enable signal in response to at least both said first and second acknowledge inputs simultaneously receiving acknowledge signals;
wherein a token received at said poll token input will pass to said poll token output in the presence of said enable signal; and
wherein said first and second acknowledge inputs are capable of receiving acknowledge signals from two other different ones of said plurality of nodes.

16. The serial poll circuit of claim 15 wherein said second acknowledge input is capable of receiving an acknowledge signals from a downstream one of said plurality of nodes in said data path;

17. The serial poll circuit of claim 16 wherein said downstream one of said plurality of nodes is two nodes downstream.

18. The serial poll circuit of claim 15 further comprising:
a plurality of peripheral devices;
at least some of said plurality of nodes being request nodes; and
each of said request nodes being connected to one of said plurality of peripheral devices.

19. The serial poll circuit of claim 15, further comprising said plurality of nodes being request nodes; and a control node at least partially controlling said plurality of nodes.

20. A serial poll circuit comprising:
a plurality of request nodes along a data path, each comprising:
a data token input and output;
first and second acknowledge inputs;
an arbitrating switch; and
an acknowledge circuit capable of generating an enable signal in response to at least both said first and second acknowledge inputs simultaneously receiving acknowledge signals;
wherein a token received at said data token input will pass to said data token output in the presence of said enable signal;
at least one of said request nodes further comprising said first acknowledge input being capable of receiving an acknowledge signal from an adjacent upstream one of said plurality of nodes in said data path; and
said second acknowledge input being capable of receiving an acknowledge signal from a downstream one of said plurality of nodes in said data path.

21. The serial poll circuit of claim 20 wherein said second acknowledge input is capable of receiving an acknowledge signal from one of said plurality of nodes in said data path that is two nodes downstream.

22. The serial poll request node of claim 20 further comprising a peripheral device operating in connection with said serial poll request node.

23. A serial poll request node, comprising:
a request input terminal, a go output terminal, an acknowledge two-prior input terminal, a mutex, a first input and corresponding first output of the mutex, a second input and corresponding second output of the mutex, a hysteresis gate, and a threshold gate;
said first input to the mutex is connected to a first input to the threshold gate;
said second input to the mutex is connected to said request input terminal;
said first output of the mutex is connected to a first input to said hysteresis gate;
said second output of the mutex is connected to a second input to the threshold gate, and
said acknowledge two-prior input terminal is connected to a second input of the hysteresis gate.

24. A serial poll circuit comprising:
a plurality of nodes including a plurality of request nodes and a control node at least partially controlling said plurality of request nodes,
a first data path, defined by said plurality of nodes, configured to transmit a token along said first data path;
a second data path, different from said first data path, defined said plurality of nodes, configured to transmit a first acknowledge signal along said second data path from one of said plurality of nodes to the adjacent upstream node; and
a third data path, including said plurality of request nodes, configured to transmit a second acknowledge signal along said third data path from one of said plurality of request nodes to the second adjacent downstream one of said plurality of request nodes,
wherein each of said plurality of request nodes transmits said token in accordance with said first and second acknowledge signals received along said second and third data paths.
